(19) United States
(12) Patent Application Publication
(10) Pub. No.: US 2025/0374645 A1
(43) Pub. Date: Dec. 4, 2025

(54) SEMICONDUCTOR DEVICE AND METHOD FOR FABRICATING THE SAME

(71) Applicant: United Semiconductor (Xiamen) Co., Ltd., Xiamen (CN)

(72) Inventors: Shouguo Zhang, Singapore (SG); Min-Hsien Chen, Taichung City (TW); Wen Yi TAN, Xiamen (CN)

(73) Assignee: United Semiconductor (Xiamen) Co., Ltd., Xiamen (CN)

(21) Appl. No.: 18/752,747

(22) Filed: Jun. 24, 2024

(30) Foreign Application Priority Data
May 28, 2024 (CN) 202410674366.0

(51) Int. Cl. H01L 29/49; H01L 21/285; H01L 27/092

(52) U.S. Cl. CPC H10D 64/667; H01L 21/28568; H10D 84/859

(57) ABSTRACT

A semiconductor device includes a gate structure. The gate structure, form bottom to top, includes a gate insulating layer, a first barrier layer and a gate conductive layer. The gate insulating layer is disposed on a substrate. The first barrier layer is disposed on the gate insulating layer. The first barrier layer includes a transition metal nitride, and a concentration of nitrogen atom of a portion of the first barrier layer adjacent to the gate insulating layer is higher than a concentration of nitrogen atom of a portion of the first barrier layer away from the gate insulating layer. The gate conductive layer is disposed on the first barrier layer.

### BACKGROUND OF THE INVENTION

### 1. Field of the Invention

The present disclosure relates to the field of semiconductor devices, and more particularly, to a semiconductor device including a barrier layer and a method for fabricating the same.

### 2. Description of the Prior Art

In the field of semiconductor devices, a gate structure usually includes a barrier layer disposed between a gate conductive material and a substrate. The properties of the barrier layer are related to the properties of the semiconductor device which is subsequently formed, such as the leakage current and the threshold voltage. Therefore, how to improve the barrier layer to enhance the performance of semiconductor devices has become an important issue for relevant industries.

### SUMMARY OF THE INVENTION

According to one aspect of the present disclosure, a semiconductor device includes a gate structure. The gate structure, form bottom to top, includes a gate insulating layer, a first barrier layer and a gate conductive layer. The gate insulating layer is disposed on a substrate. The first barrier layer is disposed on the gate insulating layer. The first barrier layer includes a transition metal nitride, and a concentration of nitrogen atom of a portion of the first barrier layer adjacent to the gate insulating layer is higher than a concentration of nitrogen atom of a portion of the first barrier layer away from the gate insulating layer. The gate conductive layer is disposed on the first barrier layer.

According to another aspect of the present disclosure, a method for fabricating a semiconductor device includes steps as follows. A gate structure is formed, which includes steps as follows. A gate insulating layer is formed on a substrate. A first barrier layer is formed on the gate insulating layer. The first barrier layer includes a transition metal nitride, and a concentration of nitrogen atom of a portion of the first barrier layer adjacent to the gate insulating layer is higher than a concentration of nitrogen atom of a portion of the first barrier layer away from the gate insulating layer. A gate conductive layer is formed on the first barrier layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3 and FIG. 4 are schematic cross-sectional views showing steps of a method for fabricating a semiconductor device according to an embodiment of the present disclosure.

FIG. 5, FIG. 6, FIG. 7 and FIG. 8 are schematic cross-sectional views showing steps of a method for fabricating a semiconductor device according to another embodiment of the present disclosure.

FIG. 9 is a schematic cross-sectional view showing a semiconductor device according to yet another embodiment of the present disclosure.

FIG. 10 is a schematic cross-sectional view showing a semiconductor device according to yet another embodiment of the present disclosure.

FIG. 11 is a schematic cross-sectional view showing a semiconductor device according to yet another embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

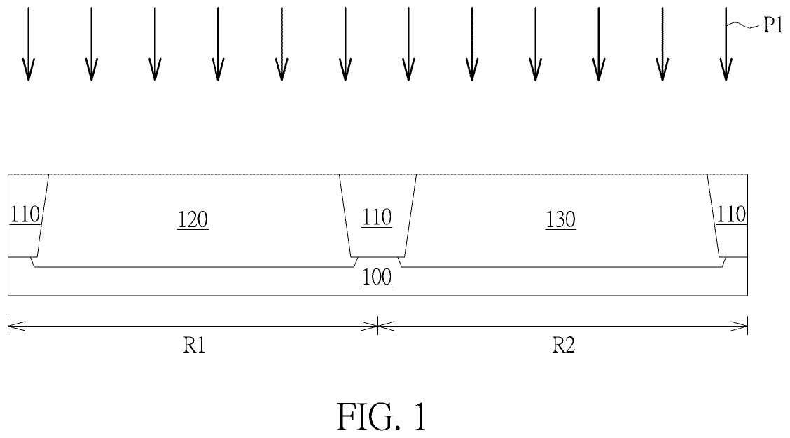

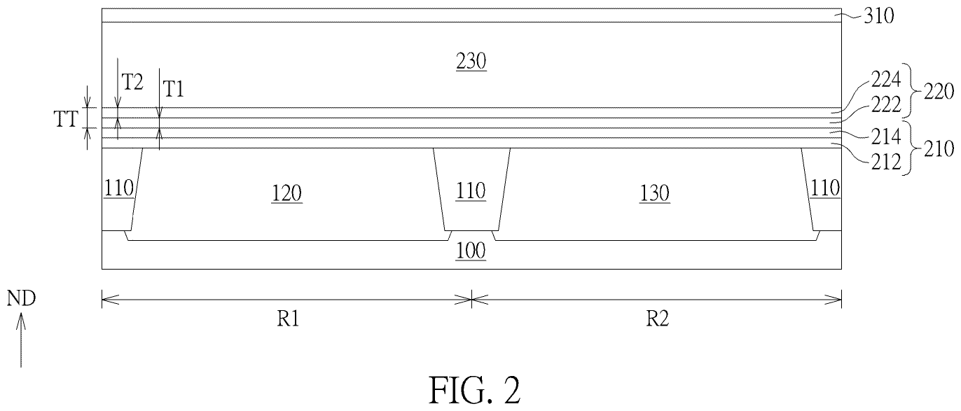

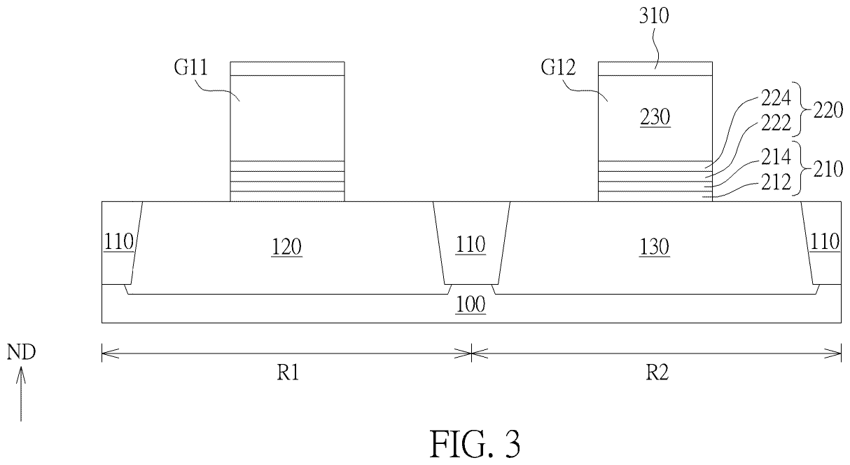

Please refer to FIG. 1 to FIG. 4, which are schematic cross-sectional views showing steps of a method for fabricating a semiconductor device according to an embodiment of the present disclosure. In FIG. 1, a substrate 100 is firstly provided. The substrate 100 may be a silicon substrate, an epitaxial silicon substrate, a silicon carbide substrate or a silicon on insulator (SOI) substrate.

Next, an insulating structure 110 is formed in the substrate 100 to define at least one transistor region, such as an n-channel metal oxide semiconductor (NMOS) transistor region R1 and a p-channel metal oxide semiconductor (PMOS) transistor region R2. The insulating structure 110 can provide electrical isolation function between different transistor regions. The insulating structure 110 may be, for example, a shallow trench isolation (STI) structure. The insulating structure 110 may include dielectric materials, such as silicon dioxide. In FIG. 1, the NMOS transistor region R1 and the PMOS transistor region R2 are adjacent to each other, which is for the convenience of drawing and explanation, and the present disclosure is not limited thereto. The positions of the NMOS transistor region R1 and the PMOS transistor region R2 on the substrate 100 may be adjusted according to design requirements.

Next, one or more ion implantation processes Pl are performed on the substrate 100 to form a first well region 120 and a second well region 130 in the NMOS transistor region R1 and the PMOS transistor region R2, respectively. In this embodiment, the first well region 120 is a p-type well region, which is implanted with p-type impurities, such as boron, indium, etc. The second well region 130 is an n-type well region, which is implanted with n-type impurities, such as arsenic, phosphorus etc. The types, the concentrations and the doping depths of the dopants in the first well region 120 and the second well region 130 may be flexibly adjusted according to actual demand.

Please refer to FIG. 2. Next, the gate structures G11 and G12 (refer to FIG. 3) are formed on the substrate 100, which may include steps as follows. First, a gate insulating layer 210 is formed on the substrate 100, which includes forming an interfacial layer 212 and a high dielectric constant material layer 214 on the substrate 100 in sequence. The interfacial layer 212 and the high dielectric constant material layer 214 may together serve as the gate insulating layer 210.

The interfacial layer 212 is optional. The interfacial layer 212 may include, for example, an oxide, a nitride, or an oxynitride. The interfacial layer 212 may be configured to solve the problem that the high dielectric constant material layer 214 may reduce the electron mobility of carriers in the channel. With the interfacial layer 212, it is favorable for further improving the properties of the semiconductor device 1a formed later. However, the present disclosure is not limited thereto. In some embodiments, the gate insulating layer 210 may only include the high dielectric constant material layer 214.

The high dielectric constant material layer 214 may include a dielectric material with a dielectric constant greater than 4, such as hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

Next, a first barrier layer 220 is formed on the gate insulating layer 210. The first barrier layer 220 may include a transition metal nitride, such as titanium nitride. Moreover, a concentration of nitrogen atom of a portion of the first barrier layer 220 adjacent to the gate insulating layer 210 is higher than a concentration of nitrogen atom of a portion of the first barrier layer 220 away from the gate insulating layer 210.

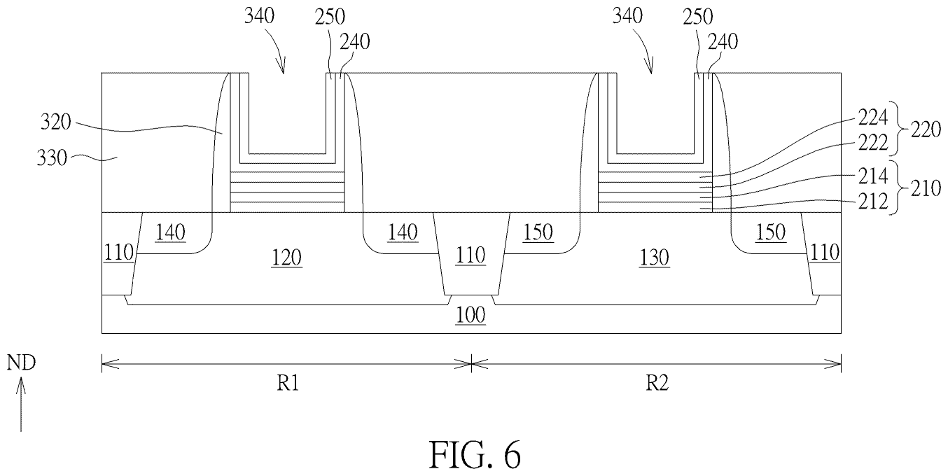

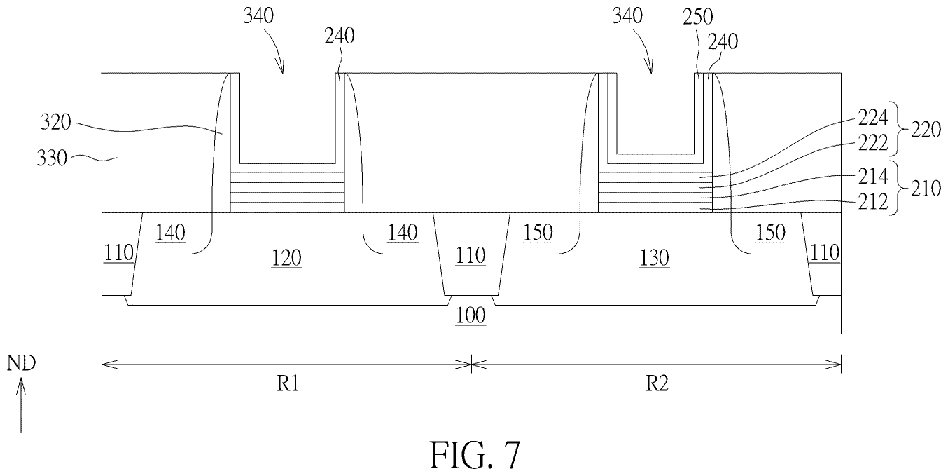

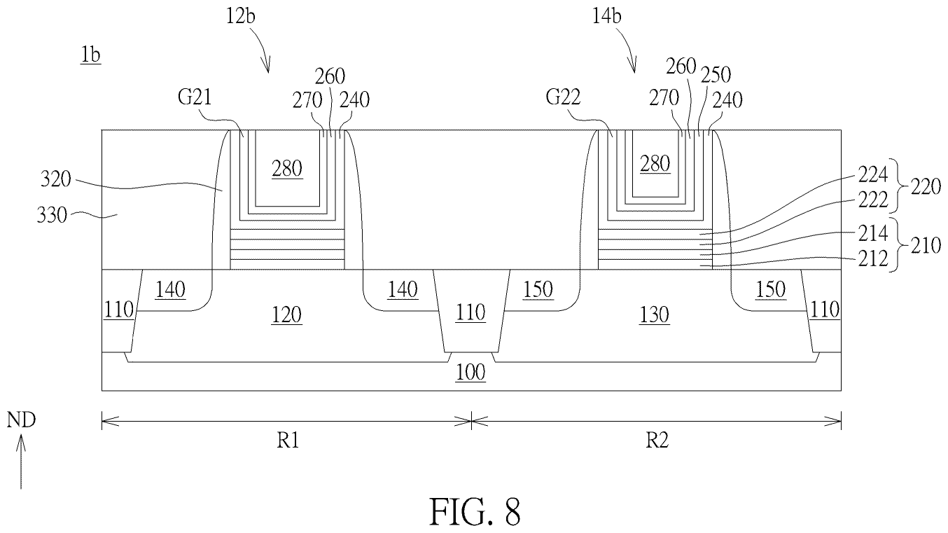

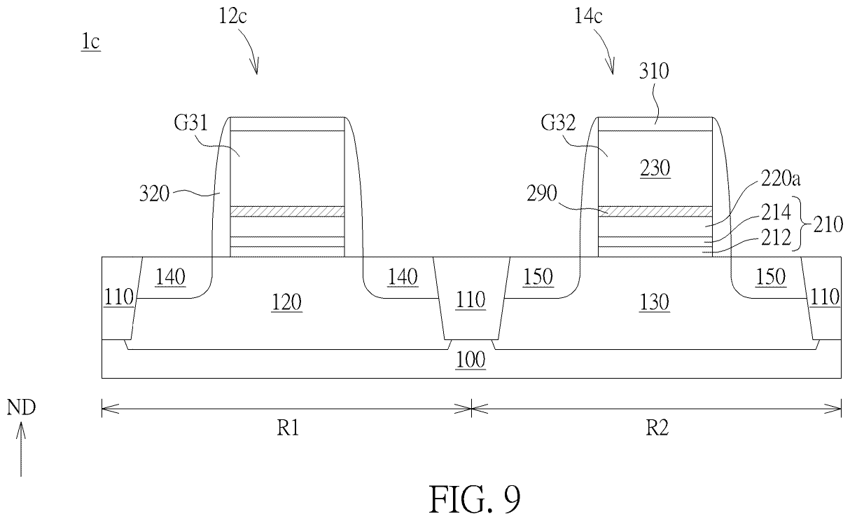

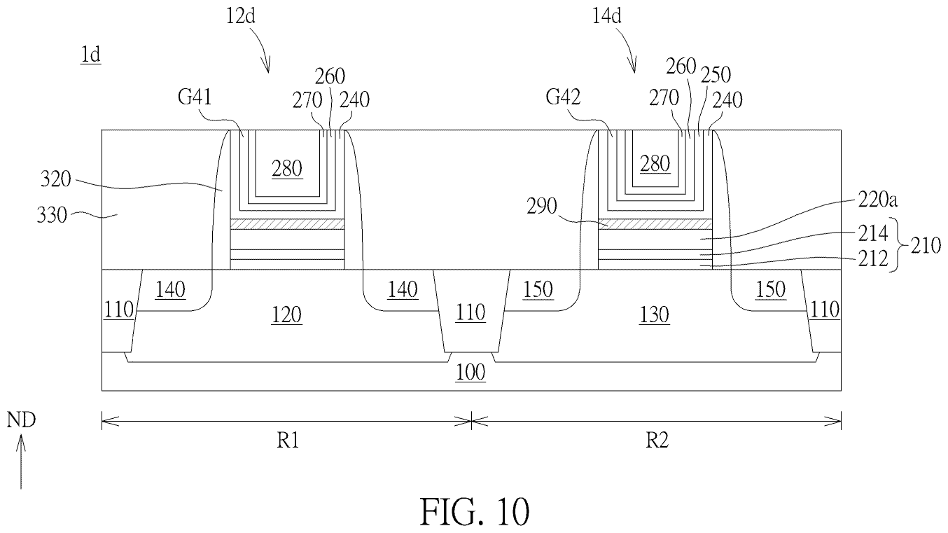

In the embodiment of FIG. 2, the first barrier layer 220 includes a first sub-layer 222 and a second sub-layer 224 from bottom to top. Therefore, forming the first barrier layer 220 includes forming the first sub-layer 222 on the gate insulating layer 210 and forming the second sub-layer 224 on the first sub-layer 222. The first sub-layer 222 is closer to the gate insulating layer 210 than the second sub-layer 224. The first sub-layer 222 may be regarded as the aforementioned “a portion of the first barrier layer 220 adjacent to the gate insulating layer 210”, and the second sub-layer 224 may be regarded as the aforementioned “a portion of the first barrier layer 220 away from the gate insulating layer 210”. The concentration of nitrogen atom of the first sub-layer 222 is higher than the concentration of nitrogen atom of the second sub-layer 224. In the embodiment of FIG. 2, the first barrier layer 220 is a double-layer structure, but not limited thereto. The number of layers of the first barrier layer 220 may be adjusted according to actual needs. For example, the first barrier layer 220 may be a single-layer structure, as shown in FIGS. 9 and 10 below. In other embodiments, the first barrier layer 220 may also be a multi-layer structure with more than two layers (not shown). In this case, the concentration of nitrogen atom of a sub-layer closest to the gate insulating layer 210 is higher than that of a sub-layer farthest from the gate insulating layer 210.

The first barrier layer 220 may be formed by a physical vapor deposition (PVD) process such as radio-frequency sputtering deposition, in which the target material includes a transition metal identical to a transition metal of the aforementioned transition metal nitride, and a nitrogen gas is introduced into the physical vapor deposition chamber. The concentration of nitrogen atom of the first sub-layer 222 may be controlled to be higher than the concentration of nitrogen atom of the second sub-layer 224 by adjusting the flow rate of the nitrogen gas.

According to an embodiment of the present disclosure, a flow rate of the nitrogen gas for forming the first sub-layer 222 may be greater than or equal to 50 sccm, and a resistivity of the first sub-layer 222 may range from 1.8 Ω μm to 3.50 Ω·μm. A flow rate of the nitrogen gas for forming the second sub-layer 224 may be greater than or equal to 0 and less than or equal to 20 sccm, and a resistivity of the second sub-layer 224 may range from 0.9 Ω·μm to 1.7 Ω·μm. In other words, the concentration of nitrogen atom of the transition metal nitride may affect the electrical properties of the transition metal nitride. The transition metal nitride of the first sub-layer 222 is in a first state with a stronger insulating property (larger resistivity), and the transition metal nitride of the second sub-layer 224 is in a second state with a stronger metallic property (lower resistivity). When the flow rate of the nitrogen gas is greater than 20 sccm and less than 50 sccm, the transition metal nitride formed thereby is in a transition state between the first state and the second state and has a relatively unstable property, which tends to cause instability in the process. In the present disclosure, with the flow rate of the nitrogen gas for forming the first sub-layer 222 being greater than or equal to 50 sccm, and with the flow rate of the nitrogen gas for forming the second sub-layer 224 being greater than or equal to 0 and less than or equal to 20 sccm, it is beneficial to avoid the instability in the process. Accordingly, the properties and the yield of the semiconductor device 1a formed later can be further improved.

In addition, the flow rate of the nitrogen gas for forming the second sub-layer 224 may be equal to 0. In this case, the second sub-layer 224 is made of the transition metal of the aforementioned transition metal nitride. That is, the second sub-layer 224 is made of a pure metal rather than a metal compound. In other words, the aforementioned “the first barrier layer 220 may include a transition metal nitride” covers the situations that the entire first barrier layer 220 is made of the transition metal nitride and only a portion of the first barrier layer 220 is made of the transition metal nitride. In addition, the flow rate of the nitrogen gas for forming the first sub-layer 222 may be fixed, so that the concentration of nitrogen atom in the first sub-layer 222 is substantially fixed. The flow rate of the nitrogen gas for forming the second sub-layer 224 may be fixed, so that the concentration of nitrogen atom in the second sub-layer 224 is substantially fixed. That is, the first barrier layer 220 defines a normal direction ND. The normal direction ND may be, for example, perpendicular to the top surface (not labeled) of the substrate 100. The concentration of nitrogen atom of the first sub-layer 222 is substantially fixed along the normal direction ND, and the concentration of nitrogen atom of the second sub-layer 224 is substantially fixed along the normal direction ND. However, the present disclosure is not limited thereto. When forming the first sub-layer 222 and/or the second sub-layer 224, the flow rate of nitrogen gas can be changed gradually, such as decreased gradually, so that the concentration of nitrogen atom of the first sub-layer 222 and/or the second sub-layer 224 decreases gradually along the normal direction ND from bottom to top. When the flow rate of the nitrogen gas for forming the first sub-layer 222 and/or the second sub-layer 224 is changed gradually, the flow rate of the nitrogen gas is preferably out of a range greater than 20 sccm and less than 50 sccm, which is beneficial to reduce the instability in the process.

Compared with a first barrier layer 220 having a fixed concentration of nitrogen atom, when the first barrier layer 220 has a lower concentration of nitrogen atom, the barrier effect provided thereby is poor, which may cause the semiconductor device 1a formed later to generate the problem of positive bias temperature instability (PBTI); when the first barrier layer 220 has a higher concentration of nitrogen atom, the barrier effect provided thereby is better, but the energy gap of the gate conductive layer 230 formed later is affected, which is unfavorable for reducing the junction leakage current. In other words, when the concentration of nitrogen atom of the first barrier layer 220 is fixed, the barrier effect and the ability to reduce the junction leakage current cannot not meet the requirement at the same time. In the present disclosure, with the portion of the first barrier layer 220 adjacent to the gate insulating layer 210 having a higher concentration of nitrogen atom, and the portion of the first barrier layer 220 away from the gate insulating layer 210 (i.e., the portion of the first barrier layer 220 closer to the gate conductive layer 230) having a lower concentration of nitrogen atom, it is beneficial to maintain or improve the barrier effect and reduce the junction leakage current at the same time.

The thickness TT of the first barrier layer 220 may range from 20 angstroms to 30 angstroms. The first sub-layer 222 has a first thickness T1, the second sub-layer 224 has a second thickness T2, and a ratio of the first thickness T1 to the second thickness T2 may range from ⅓ to 3. Thereby, it is beneficial to allow the barrier effect and the ability to reduce the junction leakage current provided by the first barrier layer 220 to meet the requirement.

Please continue to refer to FIG. 2. Next, a gate conductive layer 230 is formed on the first barrier layer 220. The gate conductive layer 230 may include a non-metallic conductor, such as doped or undoped amorphous silicon (a-Si) or polycrystalline silicon. Next, a hard mask 310 is formed on the gate conductive layer 230. The hard mask 310 may be a single-layer structure or a multi-layer structure (not shown). For example, the hard mask 310 may include oxides, nitrides, or a multi-layer structure composed of oxides and nitrides. When the hard mask 310 is a multi-layer structure, it is beneficial to accurately define the patterns of the gate structures G11 and G12 formed later.

Next, as shown in FIG. 3, the hard mask 310, the gate conductive layer 230, the first barrier layer 220, and the gate insulating layer 210 may be patterned by photolithography and etching processes to complete the fabrication of the gate structures G11 and G12. Herein, the gate structures G11 and G12 have the same structure.

Next, as shown in FIG. 4, two spacers 320 are formed to surround the gate structures G11 and G12, respectively. Each of the spacers 320 may be a single-layer structure or a multi-layer structure (not shown), and each of the spacers 320 may include oxides and/or nitrides, such as silicon dioxide, silicon nitride, silicon oxynitride or silicon nitride carbide. Before forming the spacers 320, light doped drains (LDDs) (not shown) may be formed in the substrate 100. The LDDs are located at two sides of the gate structures G11 and G12 and are located below the spacers 320. After the spacers 320 are formed, the first source/drain regions 140 may be formed in the first well region 120 of the substrate 100, and the second source/drain regions 150 may be formed in the second well region 130 of the substrate 100. Thereby, the fabrication of the semiconductor device 1a is completed.

The conductivity type of the first source/drain region 140 is opposite to the conductivity type of the first well region 120, and the conductivity type of the second source/drain region 150 is opposite to the conductivity type of the second well region 130. Herein, the conductivity type of each of the first source/drain regions 140 is n type, and the first source/drain regions 140 are implanted with n-type impurities, such as arsenic, phosphorus, etc. The conductivity type of each of the second source/drain regions 150 is p type, and the second source/drain regions 150 are implanted with p-type impurities, such as boron, indium, etc. In other embodiments, an isotropic or anisotropic etching process may be performed to form recesses (not shown) in the substrate 100 at two sides of the gate structure G12 of the PMOS transistor region R2, and then a selective epitaxial growth (SEG) process may be performed to form an epitaxial layer capable of providing stress in the recesses, such as a silicon germanium epitaxial layer. Next, an ion implantation process is performed to implant p-type impurities, such as boron, indium, etc., in the epitaxial layer to form the second source/drain regions (not shown) capable of providing stress.

Please refer to FIG. 4, which is a schematic cross-sectional view of the semiconductor device 1a according to an embodiment of the present disclosure. The semiconductor device 1a includes the substrate 100, the NMOS transistor 12a and the PMOS transistor 14a. The substrate 100 includes an NMOS transistor region R1 and a PMOS transistor region R2. The NMOS transistor 12a is disposed in the NMOS transistor region R1, and the PMOS transistor 14a is disposed in the PMOS transistor region R2.

The NMOS transistor 12a includes the first well region 120, the two first source/drain regions 140, the gate structure G11 and the spacer 320. The first well region 120 is formed in the substrate 100. The two first source/drain regions 140 are formed in the first well region 120. The gate structure G11 is disposed on the substrate 100. The spacer 320 surrounds the gate structure G11. The PMOS transistor 14a includes the second well region 130, the two second source/drain regions 150, the gate structure G12 and the spacer 320. The second well region 130 is formed in the substrate 100. The two second source/drain regions 150 are formed in the second well region 130. The gate structure G12 is disposed on the substrate 100. The spacer 320 surrounds the gate structure G12.

The gate structure G11 includes, from bottom to top, the gate insulating layer 210, the first barrier layer 220 and the gate conductive layer 230. The gate insulating layer 210 is disposed on the substrate 100. The first barrier layer 220 is disposed on the gate insulating layer 210. The gate conductive layer 230 is disposed on the first barrier layer 220. The first barrier layer 220 includes the transition metal nitride, and the concentration of nitrogen atom of the portion of the first barrier layer 220 adjacent to the gate insulating layer 210 is higher than the concentration of nitrogen atom of the portion of the first barrier layer 220 away from the gate insulating layer 210.

Specifically, the gate insulating layer 210 includes the interfacial layer 212 and the high dielectric constant material layer 214 from bottom to top. The first barrier layer 220 includes the first sub-layer 222 and the second sub-layer 224 from bottom to top. The concentration of nitrogen atom of the first sub-layer 222 is higher than the concentration of nitrogen atom of the second sub-layer 224. The gate conductive layer 230 includes a non-metallic conductor. The structure of the gate structure G12 is identical to that of the gate structure G11, and is not repeated herein.

In this embodiment, with the concentration of nitrogen atom of the first sub-layer 222 being higher than that of the second sub-layer 224, it is beneficial to improve the barrier effect and reduce the junction leakage current. For other details about the semiconductor device 1a, references may be made to above description and are not repeated herein.

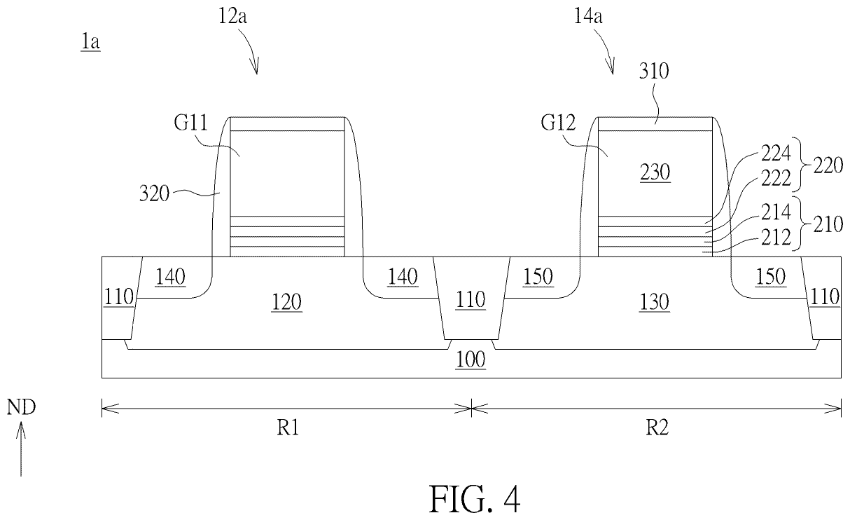

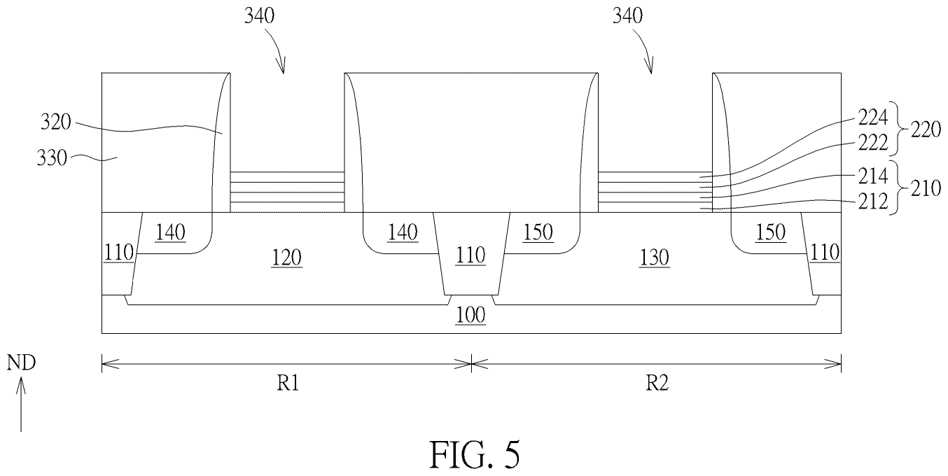

Please refer to FIGS. 5 to 8, which are schematic cross-sectional views showing steps of a method for fabricating a semiconductor device according to another embodiment of the present disclosure. In this embodiment, the semiconductor device 1a in FIG. 4 is subjected to a replacement metal gate (RMG) process to convert the gate structures G11 and G12 into gate structures G21 and G22 to obtain the semiconductor device 1b shown in FIG. 8.

As shown in FIG. 5, after forming the semiconductor device 1a, a dielectric layer 330 is formed on the substrate 100 to cover the gate structures G11 and G12 and the spacers 320. Next, a planarization process such as chemical mechanical polishing (CMP) is performed to remove a portion of the dielectric layer 330, so that the dielectric layer 330 is aligned with top surfaces of the gate structures G11 and G12 to expose the hard masks 310 of the gate structures G11 and G12. The dielectric layer 330 may include silicon dioxide, tetraethoxysilane (TEOS), etc.

Next, an etching process may be performed to remove the hard masks 310 and the gate conductive layers 230 of the gate structures G11 and G12 to form recesses 340 in the spacers 320. Next, as shown in FIG. 6, a second barrier layer 240 and a work function metal layer 250 are sequentially formed in the two recesses 340. The work function metal layer 250 is located on the second barrier layer 240. Next, as shown in FIG. 7, a patterned mask (not shown) is formed to cover the PMOS transistor region R2, and the work function metal layer 250 in the NMOS transistor region R1 is removed by an etching process. Next, the patterned mask is removed. Next, as shown in FIG. 8, a work function metal layer 260 and a third barrier layer 270 are formed sequentially in the two recesses 340. As last, a metallic conductor 280 is filled into the recesses 340, in which the remaining space of the recesses 340 are filled by the metallic conductor 280, and the metallic conductor 280 is located on the work function metal layer 260 through the third barrier layer 270. Thereby, the fabrication of the semiconductor device 1b is completed.

Each of the second barrier layer 240 and the third barrier layer 270 may include a transition metal nitride. The materials of the first barrier layer 220, the second barrier layer 240 and the third barrier layer 270 may be the same or different. According to an embodiment of the present disclosure, the first barrier layer 220 includes titanium nitride, the second barrier layer 240 includes tantalum nitride (TaN), and the third barrier layer 270 includes titanium nitride. The work function metal layers 250 and 260 can be used to adjust the work functions of the gate structures G21 and G22, so that the gate structures G21 and G22 are suitable for the NMOS transistor 12b and the PMOS transistor 14b, respectively. In this embodiment, the work function metal layer 250 may be a p-type work function metal layer, which may be made of a metal material with a work function ranging from 4.8 eV to 5.2 eV, such as titanium nitride (TiN), tantalum nitride or tantalum carbide (TaC), etc., but not limited thereto. The work function metal layer 260 is preferably an n-type work function metal layer, which may be made of a metal material with a work function ranging from 3.9 eV to 4.3 eV, such as titanium aluminide (TiAl), zirconium aluminide (ZrAl), tungsten aluminide (WAl), tantalum aluminide (TaAl), hafnium aluminide (HfAl) or titanium aluminum carbide (TiAlC), but not limited thereto.

The aforementioned film layers, such as the interfacial layer 212, the high dielectric constant material layer 214, the first sub-layer 222, the second sub-layer 224, the gate conductive layer 230, the hard mask 310, the spacer 320, the second barrier layer 240, the work function metal layers 250 and 260, the third barrier layer 270 and the metallic conductor 280, may be formed by any suitable methods. For example, the methods may be, but are not limited to, molecular-beam epitaxy (MBE), physical vapor deposition (PVD), chemical vapor deposition (CVD), metal organic chemical vapor deposition (MOCVD), sub-atmospheric chemical vapor deposition (SACVD), plasma-enhanced chemical vapor deposition (PECVD), hydride vapor phase epitaxy (HVPE) and atomic layer deposition (ALD).

Please refer to FIG. 8, which is a schematic cross-sectional view showing a semiconductor device 1b according to another embodiment of the present disclosure. The main difference between the semiconductor device 1b and the semiconductor device 1a is that the gate structure G21 of the NMOS transistor 12b and the gate structure G22 of the PMOS transistor 14b are metal gates, while the gate structure G11 of the NMOS transistor 12a and the gate structure G12 of the PMOS transistor 14a are non-metal gates.

The gate structure G21 includes, from bottom to top, the gate insulating layer 210, the first barrier layer 220, the second barrier layer 240, the work function metal layer 260, the third barrier layer 270 and the metallic conductor 280, in which the second barrier layer 240, the work function metal layer 260, the third barrier layer 270 and the metallic conductor 280 together form a gate conductive layer (not labeled). Each of the second barrier layer 240, the work function metal layer 260 and the third barrier layer 270 has a U-shaped cross-section.

The gate structure G22 includes, from bottom to top, the gate insulating layer 210, the first barrier layer 220, the second barrier layer 240, the work function metal layer 250, the work function metal layer 260, the third barrier layer 270 and the metallic conductor 280, in which the second barrier layer 240, the work function metal layers 250 and 260, the third barrier layer 270 and the metallic conductor 280 together form a gate conductive layer (not labeled). Each of the second barrier layer 240, the work function metal layers 250 and 260 and the third barrier layer 270 has a U-shaped cross section.

For other details about the semiconductor device 1b, references may be made to the relevant description of the semiconductor device 1a above, and are not repeated herein.

Please refer to FIG. 9, which is a schematic cross-sectional view showing a semiconductor device 1c according to yet another embodiment of the present disclosure. The main difference between the semiconductor device 1c and the semiconductor device 1a is that a gate structure G31 of an NMOS transistor 12c is different from the gate structure G11 of the NMOS transistor 12a, and a gate structure G32 of a PMOS transistor 14c is different from the gate structure G12 of the PMOS transistor 14a.

Compared with gate structure G11, a first barrier layer 220a of the gate structure G31 is a single-layer structure. The first barrier layer 220a defines a normal direction ND, and a concentration of nitrogen atom of the first barrier layer 220a decreases gradually (such as decreases in gradient) along the normal direction ND from bottom to top. With the portion of the first barrier layer 220a adjacent to the gate insulating layer 210 having a higher concentration of nitrogen atom, and with the portion of the first barrier layer 220a away from the gate insulating layer 210 (i.e., the portion closer to the gate conductive layer 230) having a lower concentration of nitrogen atom, it is beneficial to maintain or improve the barrier effect of the first barrier layer 220a and reduce the junction leakage current at the same time.

The gate structure G31 may further include a composite material layer 290 disposed between the first barrier layer 220a and the gate conductive layer 230. For example, the process conditions such as temperature for forming the gate conductive layer 230, the hard mask 310, the spacer 320 and other film layers (corresponding to the steps shown in FIG. 2 to FIG. 4) may be controlled to allow the gate conductive layer 230 and the first barrier layer 220a to react to form a composite material layer 290 at the interface between the first barrier layer 220a and the gate conductive layer 230. In other words, the constituent elements of the composite material layer 290 are identical to some of the constituent elements of the first barrier layer 220a, and are identical to some of the constituent elements of the gate conductive layer 230. For example, the composite material layer 290 includes a transition metal, and the transition metal is identical to the transition metal of the transition metal nitride of the first barrier layer 220a. More specifically, according to an embodiment of the present disclosure, when the first barrier layer 220a includes titanium nitride, the composite material layer 290 includes titanium accordingly. For example, the gate conductive layer 230 includes amorphous silicon or polycrystalline silicon, and the composite material layer 290 includes silicon accordingly. According to an embodiment of the present disclosure, the composite material layer 290 may include titanium salicide (TiSix), and may optionally include titanium oxynitride (TiON). According to an embodiment of the present disclosure, the thickness of the composite material layer 290 may range from 0.5 nm to 1.5 nm.

In the present disclosure, with the portion of the first barrier layer 220a closer to the gate conductive layer 230 having a lower concentration of nitrogen atom, it is beneficial to combine the constituent elements of the gate conductive layer 230 with the transition metal of the first barrier layer 220a to form the composite material layer 290. The composite material layer 290 can further reduce the junction leakage current. The structure of the gate structure G32 is identical to that of the gate structure G3, and are not repeated herein. For other details about the semiconductor device 1c, references may be made to the relevant description of the semiconductor device 1a above, and are not repeated herein.

Please refer to FIG. 10, which is a schematic cross-sectional view showing a semiconductor device 1d according to yet another embodiment of the present disclosure. The main difference between the semiconductor device 1d and the semiconductor device 1c is that a gate structure G41 of an NMOS transistor 12d is different from the gate structure G31 of the NMOS transistor 12c, and a gate structure G42 of a PMOS transistor 14d is different from the gate structure G32 of the PMOS transistor 14c.

The semiconductor device 1c in FIG. 9 is subjected to a replacement metal gate process to obtain the semiconductor device 1d in FIG. 10. For other details about the semiconductor device 1d, references may to made to the relevant descriptions of the semiconductor devices 1b and 1c above, and are not repeated herein.

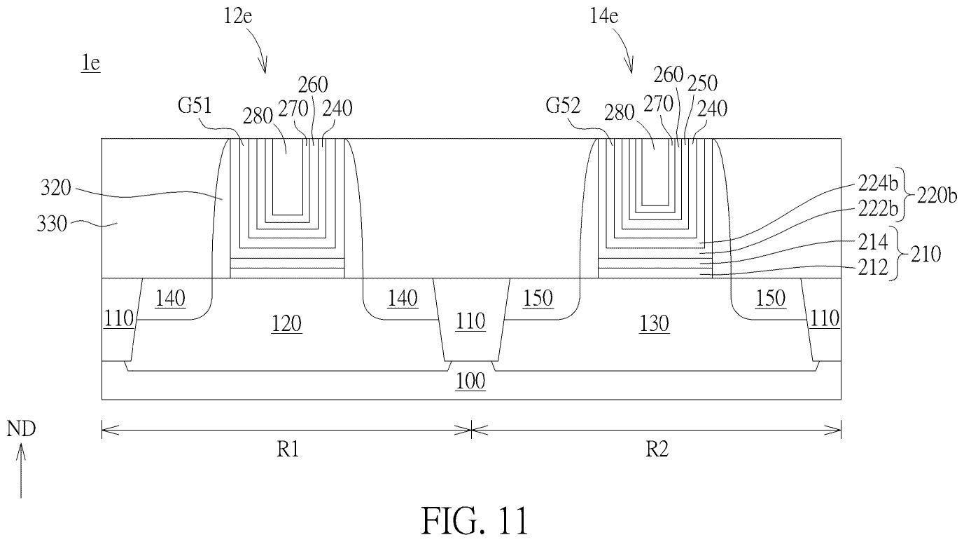

Please refer to FIG. 11, which is a schematic cross-sectional view showing a semiconductor device 1e according to yet another embodiment of the present disclosure. The main difference between the semiconductor device 1e and the semiconductor device 1b is that a gate structure G51 of an NMOS transistor 12e is different from the gate structure G21 of the NMOS transistor 12b, and a gate structure G52 of a PMOS transistor 14e is different from the gate structure G22 of the PMOS transistor 14b.

Compared with the gate structures G21 and G22, each of a first sub-layer 222b and a second sub-layer 224b of a first barrier layer 220b of each of the gate structures G51 and G52 has a U-shaped cross section. Specifically, the semiconductor device 1b is formed by a high-k first process of a gate last process, while the semiconductor device 1e is formed by a high-k last of a gate last process. For example, when performing the replacement metal gate process, not only the hard mask 310 and the gate conductive layer 230 (corresponding to the step shown in FIG. 5) are removed, but also the first barrier layer 220 is removed, and then the first sub-layer 222b and the second sub-layer 222b are deposited sequentially. Afterward, the step of FIG. 6 and the steps after FIG. 6 are performed to obtain the semiconductor device 1e. For details about the first sub-layer 222b and the second sub-layer 224b, references may be made to the details of the first sub-layer 222 and the second sub-layer 224 above. For other details about the semiconductor device 1e, references may be made to the relevant description of the semiconductor device 1b above, and are not repeated herein.

Compared with the prior art, in the present disclosure, with the first barrier layer between the gate insulating layer and the gate conductive layer having different concentrations of nitrogen atom, and the concentration of nitrogen atom of the portion of the first barrier layer adjacent to the gate insulating layer being higher than that of the portion of the first barrier layer away from the gate insulating layer, it is beneficial to improve the barrier effect and reduce the junction leakage current.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a gate structure, form bottom to top, comprising:
a gate insulating layer disposed on a substrate;
a first barrier layer disposed on the gate insulating layer, wherein the first barrier layer comprises a transition metal nitride, and a concentration of nitrogen atom of a portion of the first barrier layer adjacent to the gate insulating layer is higher than a concentration of nitrogen atom of a portion of the first barrier layer away from the gate insulating layer; and
a gate conductive layer disposed on the first barrier layer.

2. The semiconductor device of claim 1, wherein the first barrier layer defines a normal direction, and a concentration of nitrogen atom of the first barrier layer decreases gradually along the normal direction from bottom to top.

3. The semiconductor device of claim 1, wherein the first barrier layer comprises a first sub-layer and a second sub-layer from bottom to top, and a concentration of nitrogen atom of the first sub-layer is higher than a concentration of nitrogen atom of the second sub-layer.

4. The semiconductor device of claim 3, wherein a resistivity of the first sub-layer ranges from 1.8 Ω·μm to 3.5 Ω·μm, and a resistivity of the second sub-layer ranges from 0.9 Ω·μm to 1.7 Ω·μm.

5. The semiconductor device of claim 3, wherein the first sub-layer has a first thickness, the second sub-layer has a second thickness, and a ratio of the first thickness to the second thickness ranges from ⅓ to 3.

6. The semiconductor device of claim 1, wherein a thickness of the first barrier layer ranges from 20 angstroms to 30 angstroms.

7. The semiconductor device of claim 1, further comprising:
a composite material layer disposed between the first barrier layer and the gate conductive layer, wherein the composite material layer comprises silicon and a transition metal identical to a transition metal of the transition metal nitride.

8. The semiconductor device of claim 1, wherein the gate conductive layer comprises a non-metallic conductor.

9. The semiconductor device of claim 1, wherein the gate conductive layer comprises a metallic conductor.

10. The semiconductor device of claim 9, wherein the gate structure further comprises:
a second barrier layer disposed on the first barrier layer, wherein the second barrier layer has a U-shaped cross section; and
a work function metal layer disposed on the second barrier layer, wherein the work function metal layer has a U-shaped cross section.

11. A method for fabricating a semiconductor device, comprising:
forming a gate structure, comprising:
forming a gate insulating layer on a substrate;
forming a first barrier layer on the gate insulating layer, wherein the first barrier layer comprises a transition metal nitride, and a concentration of nitrogen atom of a portion of the first barrier layer adjacent to the gate insulating layer is higher than a concentration of nitrogen atom of a portion of the first barrier layer away from the gate insulating layer; and
forming a gate conductive layer on the first barrier layer.

12. The method of claim 11, wherein the first barrier layer defines a normal direction, and a concentration of nitrogen atom of the first barrier layer decreases gradually along the normal direction from bottom to top.

13. The method of claim 11, wherein forming the first barrier layer comprises:
forming a first sub-layer on the gate insulating layer; and
forming a second sub-layer on the first sub-layer, wherein a concentration of nitrogen atom of the first sub-layer is higher than a concentration of nitrogen atom of the second sub-layer.

14. The method of claim 13, wherein forming the first barrier layer comprises providing a nitrogen gas, a flow rate of the nitrogen gas for forming the first sub-layer is greater than or equal to 50 sccm, and a flow rate of the nitrogen gas for forming the second sub-layer is greater than or equal to 0 and less than or equal to 20 sccm.

15. The method of claim 13, wherein the first sub-layer has a first thickness, the second sub-layer has a second thickness, and a ratio of the first thickness to the second thickness ranges from ⅓ to 3.

16. The method of claim 11, wherein a thickness of the first barrier layer ranges from 20 angstroms to 30 angstroms.

17. The method of claim 11, further comprising:
forming a composite material layer between the first barrier layer and the gate conductive layer, wherein the composite material layer comprises silicon and a transition metal identical to a transition metal of the transition metal nitride.

18. The method of claim 11, wherein the gate conductive layer comprises a non-metallic conductor.

19. The method of claim 18, further comprising:
forming a spacer surrounding the gate structure;
removing the non-metallic conductor to form a recess in the spacer; and
filling a metallic conductor into the recess.

20. The method of claim 19, further comprising:
forming a second barrier layer in the recess, wherein the second barrier layer has a U-shaped cross section;
forming a work function metal layer in the recess and on the second barrier layer, wherein the work function metal layer has a U-shaped cross section; and
filling the metallic conductor into the recess and on the work function metal layer.
